(19) United States
(12) Patent Application Publication
(10) Pub. No.: US 2025/0098508 A1
(43) Pub. Date: Mar. 20, 2025

(54) DISPLAY PANEL TRANSFER METHOD

(71) Applicant: Samsung Display Co., LTD., Yongin-si (KR)

(72) Inventors: JEONGWEON SEO, Yongin-si (KR); JUNYOUNG LEE, Yongin-si (KR); JUNWOO YOU, Yongin-si (KR); SUNG-WOON IM, Yongin-si (KR)

(21) Appl. No.: 18/744,966

(22) Filed: Jun. 17, 2024

(30) Foreign Application Priority Data
Sep. 20, 2023 (KR) 10-2023-0125889

(51) Int. Cl. H10K 59/88

(52) U.S. Cl. CPC H10K 59/88

(57) ABSTRACT

A display panel transfer method includes providing a coating layer onto a rear surface of a display panel and providing an impact preventing layer onto a rear surface of the coating layer, wherein an area of the display panel is smaller than an area of the impact preventing layer and is larger than an area of the coating layer when viewed on a plane.

This application claims priority to Korean Patent Application No. 10-2023-0125889, filed on Sep. 20, 2023, and all the benefits accruing therefrom under 35 U.S.C. § 119, the content of which in its entirety is herein incorporated by reference.

### BACKGROUND

### 1. Field

The present invention relates to a display panel, and more particularly to a display panel transfer method.

### 2. Description of Related Art

Display devices such as televisions, monitors, smartphones, and tablets that provide images to users include a display panel that displays images. Various display panels including liquid crystal display panels, organic light emitting display panels, electro wetting display panels, and electrophoretic display panels are being developed.

Meanwhile, in recent years, research on thin display panels have been conducted to implement various types of display devices, such as display devices including curved surfaces, rollable display devices, or foldable display devices. A display panel may be accommodated in a tray or a jig to be transported.

During a process or transportation, a thin display panel may collide with the inside of a tray or jig. Cracks may occur in the display panel that collides with an inside of the tray or jig.

### SUMMARY

An embodiment of the invention is to prevent a crack from occurring in a display panel due to an impact by disposing an impact preventing layer under the display panel, the impact preventing layer having an area that is larger than that of the display panel.

According to an embodiment, a display panel transfer method includes a display panel, providing a coating layer onto a rear surface of the display panel, and providing an impact preventing layer onto a rear surface of the coating layer, and an area of the display panel is smaller than an area of the impact preventing layer, and is larger than an area of the coating layer when viewed on a plane.

According to an embodiment, a display panel transfer method includes preparing a display panel, and providing a coating layer onto a rear surface of the display panel, wherein the providing of the coating layer includes providing a flat part, wherein the flat part extends in a first direction and a second direction crossing the first direction, and providing a plurality of protrusions disposed adjacent to peripheries of the flat part, wherein an area of the flat part is smaller than an area of the display panel when viewed on a plane.

### BRIEF DESCRIPTION OF THE FIGURES

The above and other objects and features of the invention will become apparent by describing in detail embodiments thereof with reference to the accompanying drawings.

FIG. 1 is a perspective view of a display device, according to an embodiment.

FIG. 2 is an exploded perspective view of the display device illustrated in FIG. 1, according to an embodiment.

FIG. 3 is a sectional side view illustrating some components of the display device of FIG. 1, according to an embodiment.

FIG. 4 is a cross-sectional view of the display panel illustrated in FIG. 3, according to an embodiment.

FIG. 5 is a view illustrating a display panel and a coating layer, according to an embodiment.

FIG. 6 is a view illustrating the coating layer illustrated in FIG. 5, according to an embodiment.

FIG. 7A is a perspective view illustrating a method for manufacturing the coating layer illustrated in FIG. 3, according to an embodiment.

FIG. 7B is a perspective view illustrating a method for manufacturing the coating layer illustrated in FIG. 3, according to an embodiment.

FIG. 7C is a perspective view illustrating a method for manufacturing the coating layer illustrated in FIG. 3, according to an embodiment.

FIG. 7D is a perspective view illustrating a method for manufacturing the coating layer illustrated in FIG. 3, according to an embodiment.

FIG. 8 is a perspective view illustrating transfer of the display panel and the coating layer, according to an embodiment.

FIG. 9A is a perspective view illustrating a method for providing an impact preventing layer of FIG. 8, according to an embodiment.

FIG. 9B is a perspective view illustrating a method for providing an impact preventing layer of FIG. 8, according to an embodiment.

FIG. 9C is a cross-sectional view illustrating a method for providing an impact preventing layer of FIG. 8, according to an embodiment.

FIG. 9D is a cross-sectional view illustrating a method for providing an impact preventing layer of FIG. 8, according to an embodiment.

FIG. 9E is a cross-sectional view illustrating a method for providing an impact preventing layer of FIG. 8, according to an embodiment.

FIG. 9F is a perspective view illustrating a method for providing an impact preventing layer of FIG. 8, according to an embodiment.

FIG. 10A is a cross-sectional side view illustrating transfer of the display panel and the coating layer, according to an embodiment.

FIG. 10B is a cross-sectional side view illustrating transfer of the display panel and the coating layer, according to an embodiment.

FIG. 11A is a perspective view illustrating a coating layer, according to an embodiment.

FIG. 11B is a plan, rear view illustrating a coating layer, according to an embodiment.

FIG. 11C is a side view illustrating a coating layer, according to an

embodiment.

FIG. 12 is a bottom view illustrating a coating layer, according to an embodiment.

### DETAILED DESCRIPTION

The advantages and features of the invention and a method for achieving them will become clear with reference to embodiments that are described below in detail, together with the accompanying drawings. However, the invention is not limited to the embodiments disclosed hereinafter, but may be implemented in various different forms, and the embodiments simply make the disclosure of the invention complete and are provided to fully inform an ordinary person in the art, to which the invention pertains and the scope of the invention. Throughout the specification, the same reference numerals denote the same components.

The expression that an element or layer is “on”, “connected to”, or “coupled to” another element or layer means not only that the element or layer is directly on another element or layer but also that a third layer or element is interposed therebetween. Meanwhile, the expression that an element is “directly on” another element means that no third element or layer is interposed therebetween. The expression “and/or” includes each of items and all combination of one or more of them.

The expressions “below”, “beneath”, “lower”, “above” that are spatially relative terms, as illustrated in the drawings, may be used to easily describe a correlation of one element or component and another element and component. The spatially relative terms should be understood as terms including, in addition to directions illustrated in the drawings, different directions of an element during an operation thereof. Throughout the specification, the same reference numerals denote the same components.

Although the expressions first, second, and the like are used to describe various elements, components, and/or sections, it is apparent that the elements, components, and/or sections are not limited by the terms. The terms are used to simply distinguish one element, component, or section from another element, component, or section. Accordingly, it is apparent that a first element, a first component, or a first section that will be described below may be a second element, a second component, or a second section within the technical spirit of the present disclosure.

The embodiments described in the specification will be described with reference to views that are ideal schematic views of the invention. Accordingly, forms of the exemplary views may be modified depending on a manufacturing technology and/or an allowable error. Accordingly, the embodiments of the invention are not limited to the illustrated specific forms but include changes in the shapes formed according to the manufacturing process. Accordingly, the areas exemplified in the drawings have schematic attributes, and the shape of the areas exemplified in the drawings are provided to exemplify the specific shapes of the areas and are not intended to limit the scope of the invention.

The same reference numeral will be assigned to the same component. In addition, in drawings, thicknesses, proportions, and dimensions of components may be exaggerated to describe the technical features effectively. The term “and/or” includes any and all combinations of one or more of associated components.

In addition, the terms “under”, “at a lower portion”, “on”, “an upper portion” are used to describe the relationship between components illustrated in drawings. The terms are relative and are described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

Unless otherwise defined, all terms (including technical terms and scientific terms) used in the specification have the same meaning as commonly understood by one skilled in the art to which the invention belongs. Furthermore, terms such as terms defined in the dictionaries commonly used should be interpreted as having a meaning consistent with the meaning in the context of the related technology and should not be interpreted in ideal or overly formal meanings unless explicitly defined herein.

Hereinafter, embodiments of the invention will be described in more detail with reference to the accompanying drawings.

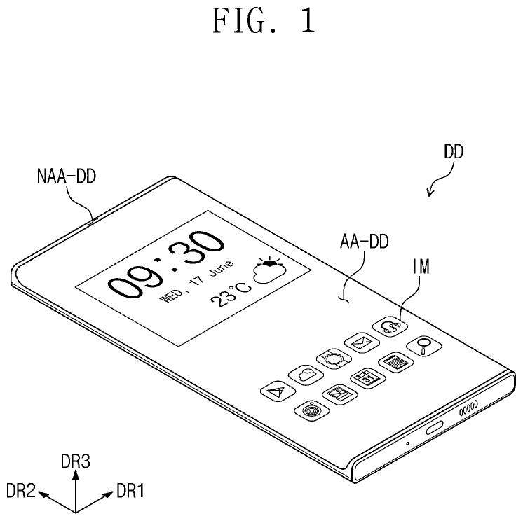

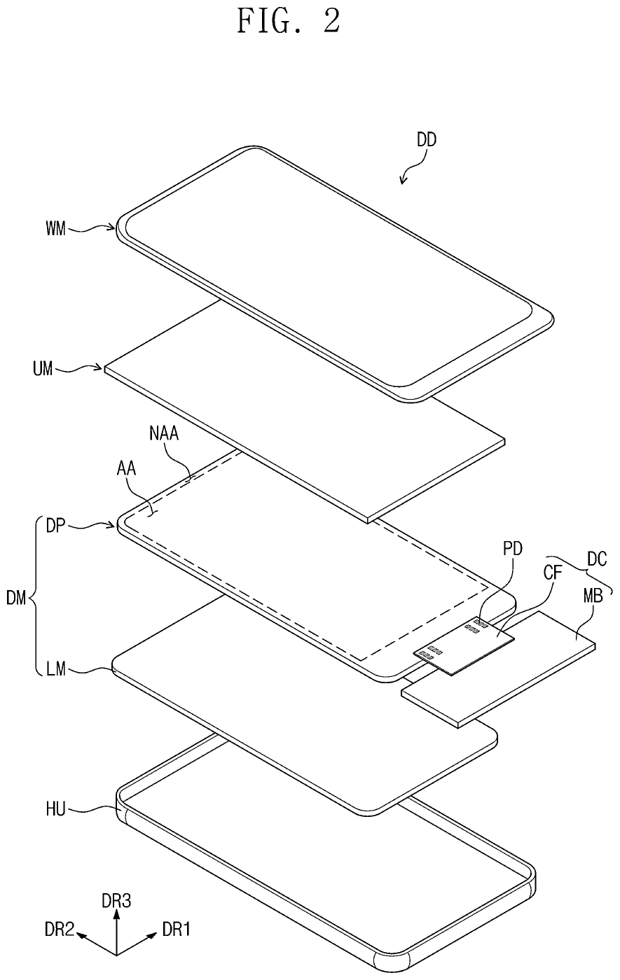

FIG. 1 is a perspective view of a display device, according to an embodiment. FIG. 2 is an exploded perspective view of the display device illustrated in FIG. 1, according to an embodiment.

In an embodiment, FIG. 1 exemplarily illustrates that a display device DD is a mobile phone. However, the display device DD is not limited thereto, and may be a middle/small-scale display device, such as a tablet, a vehicle navigation device, a gaming console, a wearable device, or a camera.

In an embodiment, the display device DD may display an image IM through an active area AA-DD. The active area AA-DD may include a plane that is defined by a first direction DR1 and a second direction DR2. The active area AA-DD may further include a curved surface that is bent from one side of the flat surface defined by the first direction DR1 and the second direction DR2. It is illustrated that the display device DD illustrated in FIG. 1 includes two curved surfaces that are bent from opposite sides of the plane defined by the first direction DR1 and the second direction DR2. However, the shape of the active area AA-DD is not limited thereto. For example, the active area AA-DD may include only the plane and may further include two or more curved surfaces on the plane, for example, four curved surfaces that are bent from four side surfaces thereof.

In an embodiment, FIG. 1 and the following drawings illustrate the first to third directions DR1, DR2, DR3, respectively, and the directions indicated by the first to third directions DR1, DR2, and DR3, respectively, described in the specification may be converted to different directions as relative concepts.

In the specification, the first direction DR1 and the second direction DR2 may be directed perpendicular to each other, and the third direction DR3 may be directed in a normal direction to the plane defined by the first direction DR1 and the second direction DR2. In the specification, the meaning of “on a plane” may mean a direction that is viewed on a plane defined by the first direction DR1 and the second direction DR2, and a thickness direction may mean the third direction DR3 that is a direction that a normal direction to the plane defined by the first direction DR1 and the second direction DR2.

In an embodiment, the display device DD may include the active area AA-DD, and a peripheral area NAA-DD that is disposed adjacent to the active area AA-DD. The active area AA-DD may correspond to a display area AA (see FIG. 2) of a display panel DP, which will be described below, and a non-display area NAA (see FIG. 2) may correspond to the peripheral area NAA-DD (see FIG. 2) of the display panel DP.

In an embodiment, the peripheral area NAA-DD is an area that interrupts an optical signal, and may be disposed on an outer side of the active area AA-DD to surround the active area AA-DD. In an embodiment, the peripheral area NAA-DD may be disposed not on a front surface but a side surface of the display device DD. In an embodiment, the peripheral area NAA-DD may be omitted.

In an embodiment and referring to FIGS. 1 and 2, the display device DD may include a window WM, a housing HU, a display module DM, a circuit board DC, and an upper member UM.

In an embodiment, the display device DD may include the window WM that is disposed on the display module DM. The window WM may provide an outer surface of the display device DD. Although not illustrated, the window WM may include a base substrate, and may further include functional layer, such as a reflection preventing layer, a fingerprint preventing layer, or an optical layer that controls a phase.

In an embodiment, the upper member UM of the display device DD may be disposed between the window WM and the display module DM. The upper member UM may include the reflection preventing layer and an input sensing sensor. The reflection preventing layer may decrease a reflection ratio of external light. The input sensing sensor may sense an external input by a user. The upper member UM may further include an adhesive layer that couples the reflection preventing layer and the input sensing sensor.

In an embodiment, the display module DM may be disposed under the upper member UM. The display module DM may include the display panel DP and a coating layer LM.

In an embodiment, the display panel DP may include the display area AA that displays the image IM, and the non-display area NAA that is disposed adjacent to the display area AA. That is, a front surface of the display panel DP may include the display area AA and the non-display area NAA. The display area AA may be an area that is activated depending on an electric signal.

In an embodiment, the non-display area NAA may be disposed adjacent to the display area AA. The non-display area NAA may surround the display area AA. Driving circuits or driving wiring lines for driving the display area AA, signal lines, pads, or electronic elements that provide electric signals to the display area AA may be disposed in the non-display area NAA.

In an embodiment, the display panel DP may include a light emitting element layer DP-ED (see FIG. 4) including organic light emitting elements, quantum dot light emitting elements, micro LED light emitting elements, or nano LED light emitting elements. The light emitting element layer DP-ED (see FIG. 4) may be a configuration that substantially generates an image.

In an embodiment, the display device DD may include the circuit board DC that is connected to the display panel DP. The circuit board DC may include a flexible board CF and a main board MB. The flexible board CF may include an insulating film, and conductive wiring lines that are mounted on the insulating film. The conductive wiring lines may be connected to pads PD and may electrically connect the circuit board DC and the display panel DP. Meanwhile, in an embodiment, the flexible board CF may be omitted, and then, the main board MB may be directly connected to the display panel DP.

In an embodiment, the main board MB may include signal lines and electronic elements that are not illustrated. The electronic elements may be connected to the signal lines and may be electrically connected to the display panel DP. The electronic elements, for example, may generate signals for generating the image IM or signals for sensing an external input, or process the sensed signals. Meanwhile, a plurality of main boards MB may be provided to correspond to electric signals that are to be generated and processed and are not limited to any one embodiment.

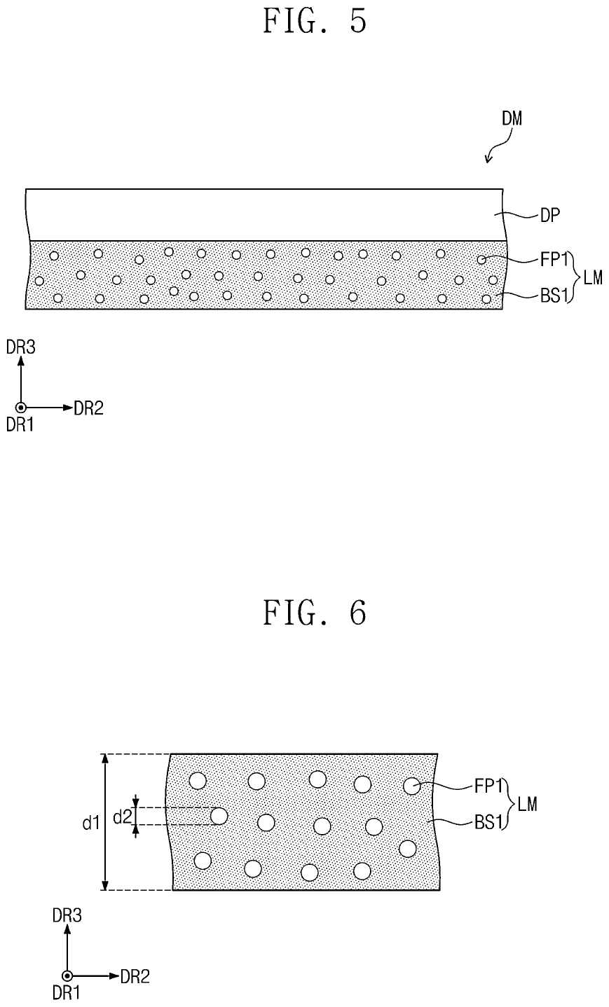

In an embodiment, the coating layer LM may be disposed under the display panel DP. The coating layer LM may support the display panel DP and may perform a heat dissipating function of discharging heat that is generated in the display panel DP. The coating layer LM will be described in detail in FIG. 5.

In an embodiment, the housing HU may be disposed under the display module DM. The display module DM may be received in the housing HU. The housing HU may be coupled to the window WM to constitute an external appearance of the display device DD.

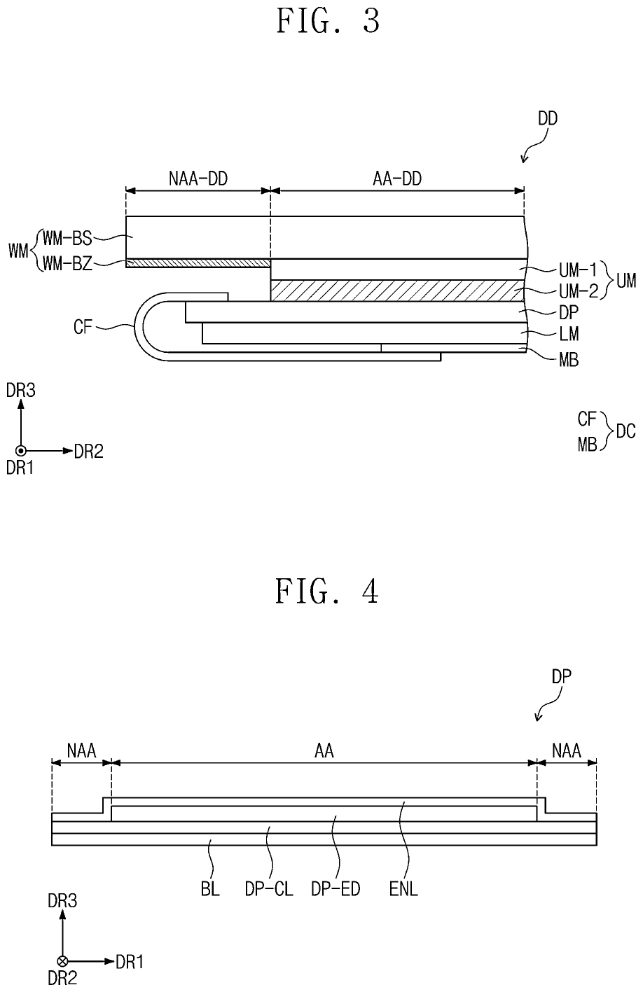

FIG. 3 is a side view illustrating some components of the display device, according to an embodiment.

In an embodiment, FIG. 3 is a side view of the display device DD, which is viewed in the first direction DR1.

In an embodiment and referring to FIG. 3, the window WM may cover a front surface of the display panel DP. The window WM may include a base substrate WM-BS and a bezel pattern WM-BZ. The base substrate WM-BS may include a first base layer, such as a glass substrate or a transparent film, which is transparent. The bezel pattern WM-BZ may have a multilayer structure. The multilayer structure may include a colored color layer and a black light shielding layer. The colored color layer and the black light shielding layer may be formed through processes of deposition, printing, and coating. The bezel pattern WM-BZ may be omitted from the window WM and may be disposed in the upper member UM.

In an embodiment, the upper member UM may include a reflection preventing layer UM-1 and an input sensor UM-2. The reflection preventing layer UM-1 may decrease a reflection ratio of external light. The reflection preventing layer UM-1 may include a phase retarder and/or a polarizer. The reflection preventing layer UM-1 may include a polarizing film or color filters. The color filters may have a specific arrangement. The color filters may be arranged in consideration of light emission colors of the pixels included in the display panel DP. The reflection preventing layer UM-1 may further include a division layer that is adjacent to the color filters.

In an embodiment, the input sensor UM-2 may include a plurality of sensing electrodes (not illustrated) for sensing an external input, trace lines (not illustrated) that are connected to the plurality of sensing electrodes, and an organic layer and/or an inorganic layer for insulating/protecting the plurality of sensing electrodes or the trace lines. The input sensor UM-2 may be a capacitive sensor, and the invention is not limited thereto.

In an embodiment, the input sensor UM-2 may be directly formed on an encapsulation layer ENL of FIG. 4, which will be described below, through continuous processes, when the display panel DP is manufactured. However, the invention is not limited thereto, and the input sensor UM-2 may be manufactured separately from the display panel DP and may be attached to the display panel DP by an adhesive layer.

In an embodiment and unlike the illustration of FIG. 3, an adhesive layer may be further disposed between the window WM and the reflection preventing layer UM-1. An adhesive layer may be further disposed between the reflection preventing layer UM-1 and the input sensor UM-2. The window WM, the reflection preventing layer UM-1, and the input sensor UM-2 may be coupled to each other through the adhesive layers.

In an embodiment, the circuit board DC may include the flexible board CF and the main board MB. The flexible board CF may be assembled while being bent. Accordingly, the main board MB may be disposed on a rear surface of the display panel DP and may be stably accommodated in a space defined by the housing HU (see FIG. 2). For example, the flexible board CF may be bent in a direction of the rear surface of the display panel DP and may be disposed on the rear surface of the coating layer LM. When the flexible board CF is bent, the main board MB may be disposed on the rear surface of the coating layer LM.

In an embodiment, the coating layer LM may be disposed on a lower surface of the display panel DP. The coating layer LM may contact the circuit board DC. Peripheries of the coating layer LM may be disposed on an inner side of the peripheries of the display panel DP. The coating layer LM will be described in detail in FIG. 5.

FIG. 4 is a cross-sectional view of the display panel illustrated in FIG. 3, according to an embodiment.

In an embodiment, the display panel DP may include a base substrate BL, a circuit layer DP-CL that is disposed on the base substrate BL, the light emitting element layer DP-ED, and the encapsulation layer ENL. The base substrate BL may include a plastic substrate, a glass substrate, a metal substrate, or an organic/inorganic complex material substrate. For example, the base substrate BL may include at least one polyimide layer.

In an embodiment, the circuit layer DP-CL may include at least one insulating layer, semiconductor patterns, and conductive patterns. The insulating layer may include at least one inorganic layer and at least one organic layer. The semiconductor patterns and the conductive patterns may constitute signal lines, a pixel driving circuit, and a scan driving circuit. Furthermore, the circuit layer DP-CL may further include a rear metal layer.

In an embodiment, the light emitting element layer DP-ED may include display elements, for example, light emitting elements. The light emitting elements may be organic light emitting elements, quantum dot light emitting elements, micro LED light emitting elements, or nano LED light emitting elements. The light emitting element layer DP-ED may further include an organic layer, such as a pixel definition film.

In an embodiment, the light emitting element layer DP-ED may be disposed in the display area AA. The non-display area NAA may be disposed at an outskirt of the display area AA to surround the display area AA, and the light emitting element layer DP-ED may not be disposed in the non-display area NAA.

In an embodiment, the encapsulation layer ENL may be disposed on the light emitting element layer DP-ED, and may cover the light emitting element layer DP-ED. The encapsulation layer ENL may be disposed on the circuit layer DP-CL to seal the light emitting element layer DP-ED. The encapsulation layer ENL may be a thin film encapsulation layer including at least one organic thin film and at least one inorganic film. The encapsulation layer ENL may have a lamination structure of an inorganic layer/organic layer/inorganic layer. The lamination structure of the encapsulation layer ENL is not limited thereto.

FIG. 5 is a view illustrating the display panel and the coating layer, according to an embodiment. FIG. 6 is a view illustrating the coating layer illustrated in FIG. 5, according to an embodiment.

In an embodiment, FIG. 5 is a cross-sectional view of the display module DM, viewed in the first direction DR1, and FIG. 6 is a cross-sectional view of the coating layer LM, viewed in the first direction DR1.

In an embodiment, the display panel DP of FIG. 5 is the same as the display panel DP of FIG. 4, and thus, a description thereof will be omitted or briefly made.

In an embodiment and referring to FIGS. 5 and 6, the coating layer LM may be disposed on a lower surface of the display panel DP. A lowermost surface of the display module DM may be defined by a lowermost surface of the coating layer LM.

In an embodiment, the coating layer LM may include a first base layer BS1 and a plurality of first fillers FP1 that are disposed in the first base layer BS1. The coating layer LM may be a single layer including the first base layer BS1 and the first fillers FP1. The first fillers FP1 may be fillers that are dispersed in the first base layer BS1.

In an embodiment, the coating layer LM may include the first base layer BS1 and the first fillers FP1, and thus, may perform various functions in the display module DM. As an example, the coating layer LM may support the display panel DP. The coating layer LM may protect the display panel DP from a physical impact that is applied from an outside of the display device DD (see FIG. 1).

In an embodiment, the coating layer LM may perform a heat dissipating function of discharging heat that is generated in the display panel DP. As an example, the coating layer LM may perform an electronic wave shielding function. However, the function of the coating layer LM is not limited thereto, and the coating layer LM may additionally perform other functions depending on characteristics, such as a thickness and a material of the coating layer LM.

In an embodiment, because the coating layer LM including the single layer performs a function of supporting the display panel DP, the heat dissipating function, and the electronic wave shielding function, the thickness of the display device DD (see FIG. 1) may be reduced and parts thereof may be simplified. When the display device DD (see FIG. 1) is manufactured, a process efficiency may be increased.

In an embodiment, a thickness d1 of the coating layer LM may be about 100 to about 1000 micrometers. A viscosity of the coating layer LM may be not less than about 100 cps and not more than about 100,000 cps. As an example, the viscosity of the coating layer LM may be about 30,000 cps. Accordingly, the coating layer LM may support the display panel DP in the display module DM.

In an embodiment, the first base layer BS1 may be a layer that provides a base material such that the first fillers FP1 is disposed. The first base layer BS1 may include an organic material. The first base layer BS1 may be formed including at least one of an acrylic polymer, a urethane polymer, a silicone polymer, and an imide polymer. The first base layer BS1 may include a material having a specific strength.

In an embodiment, each of the first fillers FP1 may include an organic material or an inorganic material. As an example, each of the first fillers FP1 may include graphite or metal particles. The first fillers FP1 may include the same material or may include different materials. Accordingly, the coating layer LM may perform functions, such as heat dissipation of the display device DD (see FIG. 1) and shielding of electronic waves.

In an embodiment, an average diameter d2 of the first fillers FP1 may be about 5 to about 200 micrometers in a condition that it is smaller than the thickness d1 of the coating layer LM. As an example, in FIG. 6, it is illustrated that sizes of the diameters of the first fillers FP1 are the same, but the invention is not limited thereto, and the first fillers FP1 may have a distribution of sizes of a single dispersion or a multi-dispersion distribution that is obtained by mixing a plurality of particles of a single dispersion distribution.

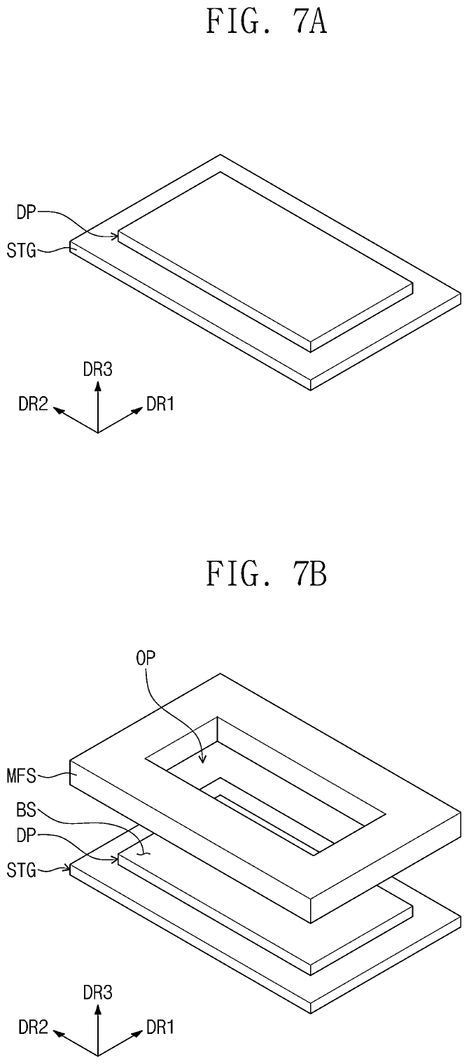

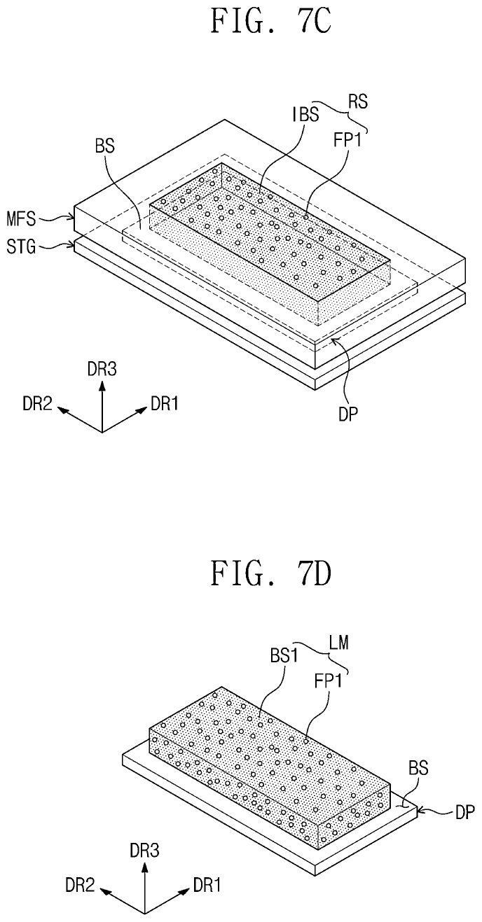

FIGS. 7A to 7D are views illustrating a method for manufacturing the coating layer illustrated in FIG. 3, according to an embodiment.

As an example, FIGS. 7A to 7D are perspective views.

In an embodiment, the display panel DP and the first fillers FP1 of FIGS. 7A to 7D are the same as the display panel DP of FIG. 4 and the first fillers FP1 of FIG. 5, and the coating layer LM of FIG. 7D is the same as the coating layer LM of FIG. 5, and thus, a description thereof will be omitted or briefly made.

In an embodiment and referring to FIG. 7A, the method for manufacturing the coating layer includes an operation of providing the display panel DP onto an upper surface of a stage STG.

In an embodiment, the stage STG may have a rectangular parallelepiped shape. An upper surface of the stage STG may have a rectangular shape having short sides that extend in the first direction DR1, and long sides that extend in the second direction DR2.

In an embodiment, the display panel DP may be disposed on an upper surface of the stage STG. The active area AA (see FIG. 2) may be disposed to face the upper surface of the stage STG.

In an embodiment, although not illustrated, a vacuum suction hole may be defined on the upper surface of the stage STG. The vacuum suction hole may be connected to an external vacuum pump. When the display panel DP is disposed on the upper surface of the stage STG, the vacuum suction holes may be converted into a vacuum state by the vacuum pump. Accordingly, the display panel DP may be fixed onto the upper surface of the stage STG.

In an embodiment and referring to FIGS. 7B and 7C, an operation of providing the display panel DP onto the upper surface of the stage STG, and then disposing a metal frame MFS on the display panel DP may be performed.

In an embodiment, the metal frame MFS may have a rectangular frame shape.

When viewed on a plane, the metal frame MFS may include short sides that extend in the first direction DR1 and long sides that extend in the second direction DR2.

In an embodiment, an opening OP may be defined in the metal frame MFS having the rectangular frame shape. When viewed on the plane, a shape of the opening OP may be rectangular.

In an embodiment, the metal frame MFS may be disposed on the stage STG and the display panel DP. The metal frame MFS may be disposed on a rear surface BS of the display panel DP. The rear surface BS of the display panel DP may be defined by a surface that is opposite to the active area AA (see FIG. 2) in the third direction DR3. The opening OP may overlap the rear surface BS of the display panel DP. When viewed on the plane, a portion of the rear surface BS of the display panel DP may be exposed from the metal frame MFS to an outside by the opening OP. When viewed on the plane, an area of the opening OP may be smaller than an area of the display panel DP.

In an embodiment and referring to FIG. 7C, an operation of disposing the metal frame MFS on the rear surface of the display panel DP, and then applying a resin RS onto the rear surface BS of the display panel DP may be performed.

In an embodiment, the resin RS may be discharged into the opening OP through a nozzle (not illustrated). The resin RS may be discharged into the opening OP and may be disposed on the rear surface BS of the display panel DP.

In an embodiment, the resin RS may include a preliminary base layer IBS, and the first fillers FP1 that are dispersed within the preliminary base layer IBS. As an example, the resin RS may include a photocurable resin.

In an embodiment and referring to FIGS. 7C and 7D, although not illustrated, an operation of disposing the resin RS in the opening OP, and then curing the resin RS may be performed. As an example, the resin RS may be cured through an ultraviolet ray. However, the invention is not limited thereto, and when the resin RS includes a thermally curable material, it may be cured through heat.

In an embodiment, the resin RS may be cured, and the coating layer LM may be provided to the rear surface BS of the display panel DP. When viewed on the plane, an area of the coating layer LM may be smaller than an area of the display panel DP. When viewed on the plane, the peripheries of the coating layer LM may be disposed on an inner side of the periphery of the display panel DP.

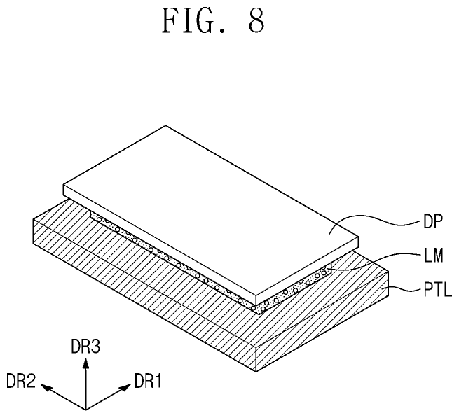

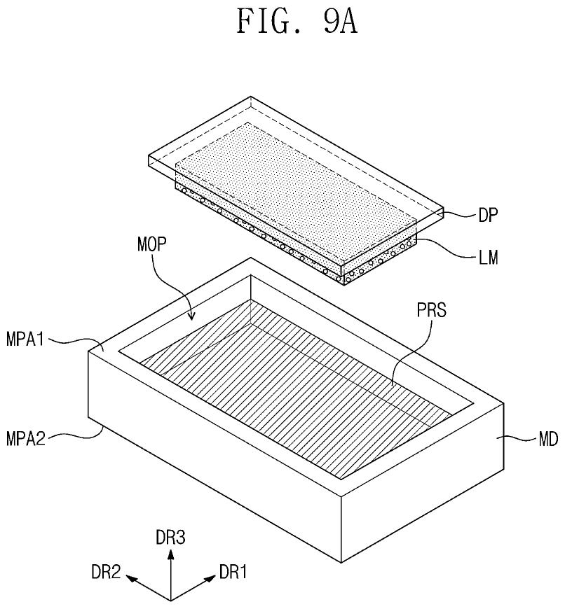

FIG. 8 is a view illustrating transfer of the display panel and the coating layer, according to an embodiment.

In an embodiment, FIG. 8 is a perspective view of the display panel DP, the coating layer LM, and an impact preventing layer PTL.

In an embodiment, because the display panel DP and the coating layer LM of FIG. 8 are the same as the display panel DP and the coating layer LM of FIG. 5, a description thereof may be omitted or briefly made.

In an embodiment and referring to FIG. 8, after the coating layer LM is disposed on the rear surface BS (see FIG. 7D) of the display panel DP, the display panel DP and the coating layer LM may be transferred for another process. Then, the impact preventing layer PTL may be disposed under the display panel DP and the coating layer LM. The impact preventing layer PTL may be disposed on a lower surface of the coating layer LM.

In an embodiment, the impact preventing layer PTL may have a rectangular parallelepiped shape. The upper surface of the impact preventing layer PTL may have a rectangular shape having short sides that extend in the first direction DR1 and long sides that extend in the second direction DR2. However, the invention is not limited thereto, and a shape of the upper surface of the impact preventing layer PTL may be variously determined.

In an embodiment, when viewed on the plane, an area of the impact preventing layer PTL may be larger than an area of the display panel DP. When viewed on the plane, an area of the impact preventing layer PTL may be larger than an area of the coating layer LM. Accordingly, when viewed on the plane, the peripheries of the impact preventing layer PTL may be disposed on an outer side of the peripheries of the display panel DP and the peripheries of the coating layer LM. The peripheries of the impact preventing layer PTL may surround the display panel DP and the coating layer LM.

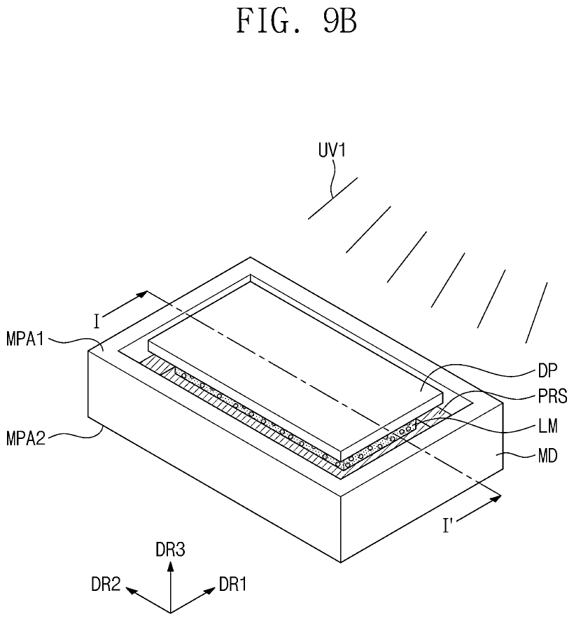

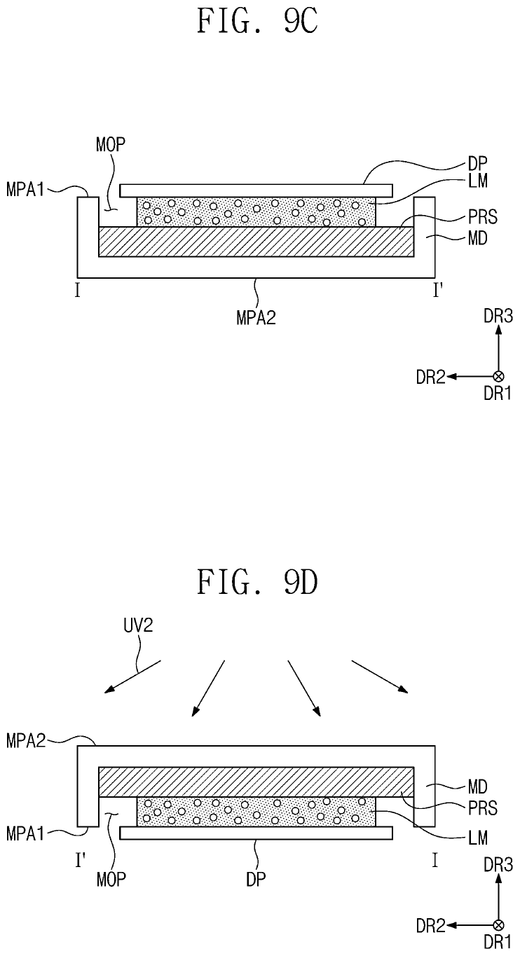

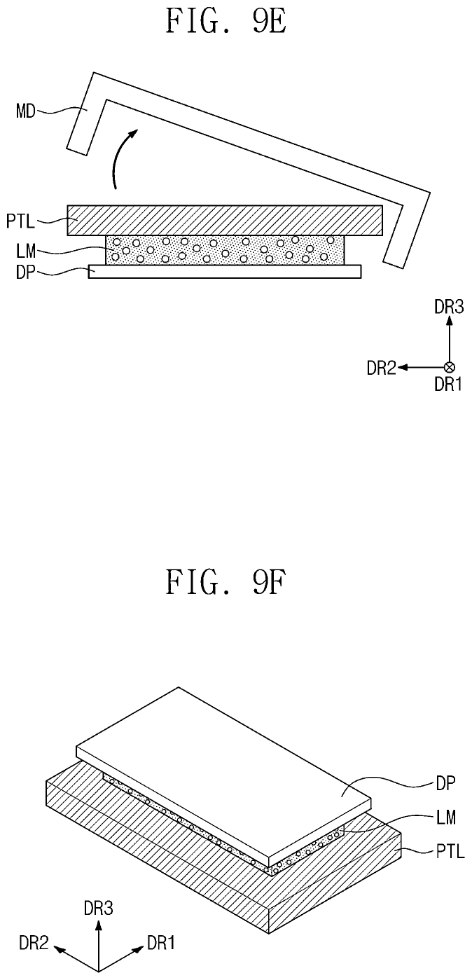

FIGS. 9A to 9F are views illustrating a method for providing the impact preventing layer of FIG. 8, according to an embodiment.

In an embodiment, FIGS. 9A, 9B, and 9F are perspective views, and FIGS. 9C, 9D, and 9E are cross-sectional views.

As an example, FIG. 9C is a cross-sectional view of line I-I′ illustrated in FIG. 9B, according to an embodiment.

In an embodiment, because the display panel DP and the coating layer LM of FIGS. 9A to 9F are the same as the display panel DP and the coating layer LM of FIG. 5, a description thereof will be omitted or briefly made.

In an embodiment and referring to FIG. 9A, the method for providing the impact preventing layer PTL (see FIG. 8) may include an operation of providing a mold MD, and an operation of providing a protective resin PRS into the mold MD.

In an embodiment, the mold MD may have a rectangular parallelepiped shape. When viewed on the plane, the mold MD may have a rectangular shape having short sides that extend in the first direction DR1 and long sides that extend in the second direction DR2. The mold MD may be optically transparent.

In an embodiment, a mold groove MOP may be defined on an upper surface of the mold MD. The mold groove MOP may extend from an upper surface MPA1 of the mold MD in the third direction DR3. When viewed on the plane, a shape of the mold groove MOP may be rectangular. When viewed on the plane, the upper surface MPA1 of the mold MD may have a rectangular frame shape. Hereinafter, the upper surface MPA1 of the mold MD may be defined as a first mold surface MPA1, and a lower surface of the mold MD may be defined as a second mold surface MPA2.

In an embodiment, the protective resin PRS may be provided to the mold groove MOP. As an example, the protective resin PRS may include an ultraviolet ray curing material. As an example, the protective resin PRS may include an acryl-based or urethane-based material.

In an embodiment and referring to FIGS. 9A and 9B, an operation of providing the display panel DP and the coating layer LM onto the mold MD when the protective resin PRS is provided to the mold groove MOP may be performed. A lower surface of the coating layer LM may be disposed to face the protective resin PRS.

In an embodiment, the display panel DP and the coating layer LM may be moved in the third direction DR3 and may be disposed on an upper surface of the protective resin PRS. The lower surface of the coating layer LM and the upper surface of the protective resin PRS may contact each other.

In an embodiment and referring to FIGS. 9B and 9C, when viewed on the plane, an area of the mold groove MOP may be larger than an area of the display panel DP. When viewed on the plane, an area of the protective resin PRS may be larger than an area of the display panel DP and an area of the coating layer LM. Accordingly, peripheries of the protective resin PRS may be disposed on an outside of the peripheries of the display panel DP and the peripheries of the coating layer LM.

In an embodiment, a primary curing operation of curing the protective resin PRS after disposing the display panel DP and the coating layer LM onto the protective resin PRS may be performed. A first ultraviolet ray UV1 may be irradiated to the protective resin PRS. The protective resin PRS may be cured by the first ultraviolet ray UV1. In the primary curing operation, the protective resin PRS may not be completely cured.

In an embodiment and referring to FIGS. 9C and 9D, after the primary curing operation, an operation of turning the mold MD, the protective resin PRS, the display panel DP, and the coating layer LM over in the third direction DR3 may be performed. The mold MD, the protective resin PRS, the display panel DP, and the coating layer LM may be reversed in an upward/downward direction to be directed in the third direction DR3. The first mold surface MPA1 may be disposed below the second mold surface MPA2. The upper surfaces of the display panel DP and the protective resin PRS may be disposed below the second mold surface MPA2 of the mold MD. Then, the protective resin PRS is cured in the primary curing operation, and thus, may not be separated from the mold groove MOP.

In an embodiment, a secondary curing operation of completely curing the protective resin PRS may be performed. A second ultraviolet ray UV2 may be irradiated onto the second mold surface MPA2 of the mold MD. Optical energy of the second ultraviolet ray UV2 may be greater than optical energy of the first ultraviolet ray UV1 (see FIG. 9C). The second ultraviolet ray UV2 may pass through the mold MD and may reach the protective resin PRS. Accordingly, the protective resin PRS may be completely cured by the second ultraviolet ray UV2.

In an embodiment and referring to FIGS. 9E and 9F, the cured protective resin PRS (see FIG. 9D) may be defined as the impact preventing layer PTL. After the impact preventing layer PTL is formed, the mold MD may be removed from the impact preventing layer PTL.

In an embodiment, the impact preventing layer PTL may be disposed on the lower surface of the coating layer LM, and the impact preventing layer PTL may be transferred together with the display panel DP and the coating layer LM. When viewed on the plane, an area of the impact preventing layer PTL may be larger than an area of the display panel DP and an area of the coating layer LM. The peripheries of the impact preventing layer PTL may be disposed on an outer side of the peripheries of the display panel DP and the peripheries of the coating layer LM.

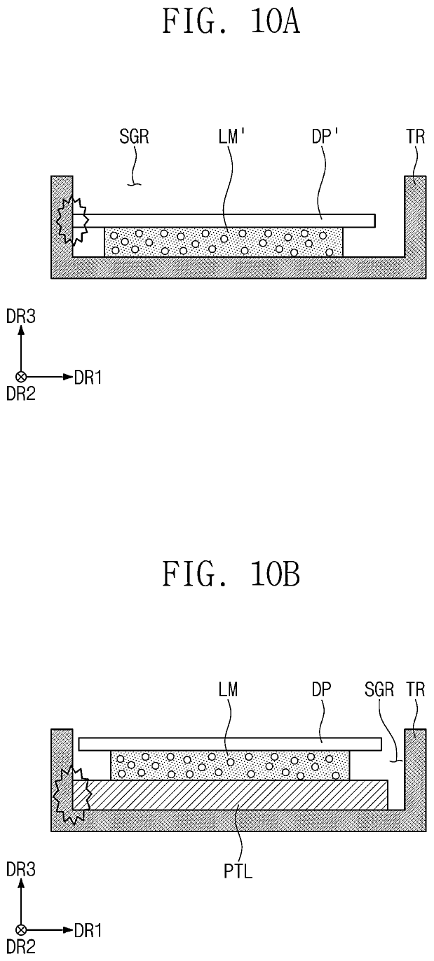

FIGS. 10A and 10B are views illustrating transfer of the display panel and the coating layer, according to an embodiment.

In an embodiment, FIG. 10A illustrates a display panel DP′ and a coating layer LM′ according to a comparative example. FIG. 10B illustrates the display panel DP, the coating layer LM, and the impact preventing layer PTL, according to an embodiment.

In an embodiment, FIGS. 10A and 10B are cross-sectional views of the display panels DP′ and DP and the coating layers LM′ and LM, viewed in the second direction DR2.

In an embodiment, because the display panels DP′ and DP and the coating layers LM′ and LM of FIGS. 10A and 10B, respectively, are the same as the display panel DP and the coating layer LM of FIG. 5, a description thereof will be omitted or briefly made.

In an embodiment, because the impact preventing layer PTL of FIG. 10B is the same as the impact preventing layer PTL of FIG. 8, a description thereof will be omitted or briefly made.

In an embodiment and referring to FIGS. 10A and 10B, as an example, the display panels DP′ and DP and the coating layers LM′ and LM, respectively, may be accommodated in a tray TR to be transferred. The display panels DP and DP′ and the coating layers LM and LM′ may be accommodated in an accommodation groove SGR that is defined in the tray TR and may be transferred. However, the invention is not limited thereto, and the display panels DP and DP′ and the coating layers LM and LM′ may be accommodated in a jig to be fed.

In an embodiment and referring to FIG. 10A, a width of the display panel DP′ in the first direction DR1 may be greater than a width of the coating layer LM′ in the first direction DR1. Although not illustrated, a width of the display panel DP′ in the second direction DR2 may be greater than a width of the coating layer LM′ in the second direction DR2.

In an embodiment, when the display panel DP′ and the coating layer LM′ are accommodated in the accommodation groove SGR of the tray TR to be transferred, the tray TR may be shaken or inclined. In this case, the display panel DP′ having a width that is larger than that of the coating layer LM′ may contact an inner side of the tray TR that defines the accommodation groove SGR earlier than the coating layer LM′. Accordingly, an external impact may be applied to the display panel DP′ and a crack or the like may be caused in the display panel DP′.

In an embodiment and referring to FIG. 10B, the impact preventing layer PTL may be disposed under the display panel DP and the coating layer LM. A width of the impact preventing layer PTL in the first direction DR1 may be greater than a width of the display panel DP in the first direction and a width of the coating layer LM in the first direction DR1. Although not illustrated, a width of the impact preventing layer PTL in the second direction DR2 may be greater than a width of the display panel DP in the second direction and a width of the coating layer LM in the second direction DR2. That is, the widths of, among the display panel DP, the coating layer LM, and the impact preventing layer PTL, the impact preventing layer PTL in the first direction DR1 and the second direction DR2 may be the greatest.

In an embodiment, when the display panel DP, the coating layer LM, and the impact preventing layer PTL is accommodated in the accommodation groove SGR of the tray TR to be transferred, the impact preventing layer PTL may contact an outer side of the tray TR that defines the accommodation groove SGR earlier than the display panel DP even when the tray TR is shaken or inclined. The display panel DP may not contact an inner side of the tray TR due to the impact preventing layer PTL. Accordingly, an external impact may not be applied to the display panel DP and damage to the display panel DP may be prevented.

In an embodiment, when another process is performed after the display panel DP, the coating layer LM, and the impact preventing layer PTL are accommodated in the accommodation groove SGR of the tray TR and transferred, the impact preventing layer PTL may be separated from the display panel DP and the coating layer LM.

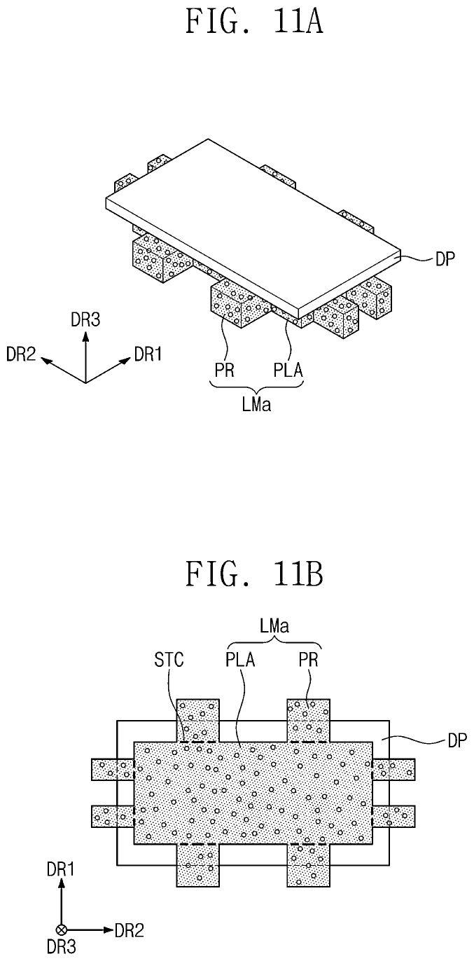

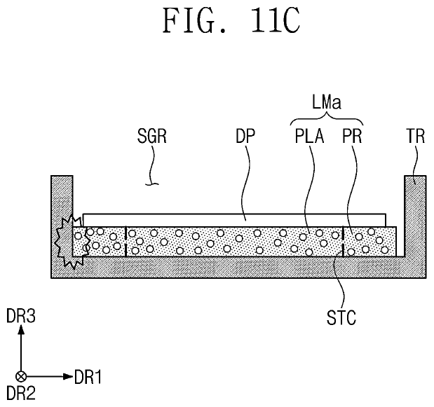

FIGS. 11A to 11C are views illustrating a coating layer, according to an embodiment.

In an embodiment, FIG. 11A is a perspective view of the display panel DP and a coating layer LMa, and FIG. 11B is a plan view of the coating layer LMa, when viewed from a rear side. FIG. 11C is a cross-sectional view of the display panel DP and the coating layer LMa in a state, in which they are accommodated in the tray TR, according to an embodiment.

In an embodiment, because the display panel DP of FIGS. 11A to 11C is the same as the display panel DP of FIG. 5, a description thereof will be omitted or briefly made.

In an embodiment and referring to FIGS. 11A and 11B, the coating layer LMa may be disposed under the display panel DP. The coating layer LMa may be disposed on the lower surface of the display panel DP.

In an embodiment, the coating layer LMa may include a flat part PLA and a plurality of protrusions PR. When viewed on the plane, the flat part PLA may have a rectangular shape having short sides that extend in the first direction DR1 and long sides that extend in the second direction DR2.

In an embodiment, when viewed on the plane, an area of the flat part PLA may be smaller than an area of the display panel DP. When viewed on the plane, peripheries of the flat part PLA may be disposed on an inner side of the peripheries of the display panel DP.

In an embodiment, the protrusions PR may be disposed at opposite sides of the flat part PLA, which are opposed to each other in the first direction DR1, and at opposite sides of the flat part PLA, which are opposed to each other in the second direction. As an example, the two protrusions PR may be disposed in each of the peripheries of the flat part PLA. The protrusions PR disposed at the same peripheries may be disposed to be spaced apart from each other in the first direction DR1 or the second direction DR2. However, this is exemplary, and the number of the protrusions PR disposed in the peripheries of the flat part PLA may not be limited thereto.

In an embodiment, the protrusions PR may extend from the flat part PLA in the first direction DR1 and the second direction DR2. Substantially, the protrusions PR and the flat part PLA may be integrally formed. Although not illustrated, the protrusions PR and the flat part PLA may be formed at the same time.

In an embodiment, although not illustrated, the resin RS (see FIG. 7C) may be applied onto the rear surface BS (see FIG. 7C) of the display panel DP and the resin RS (FIG. 7C) may be cured whereby the protrusions PR and the flat part PLA may be provided to the rear surface BS (see FIG. 7C) of the display panel DP.

In an embodiment, the protrusions PR may extend in the first direction DR1 and the second direction DR2 and may extend toward the peripheries of the display panel DP. Portions of the protrusions PR may be disposed on an outer side of the peripheries of the display panel DP.

In an embodiment, when viewed on the plane, the protrusions PR may have a rectangular shape, but the shapes of the protrusions PR may not be limited thereto.

In an embodiment, a plurality of removal grooves STC may be defined at borders of the flat part PLA and the protrusions PR. The removal grooves STC may be arranged in the first direction DR1 or the second direction DR2 along the peripheries of the flat part PLA.

In an embodiment, as the removal grooves STC are defined, the flat part PLA and the protrusions PR may be easily separated. The separation of the flat part PLA and the protrusions PR will be described below.

In an embodiment and referring to FIGS. 11A to 11C, the display panel DP and the coating layer LMa may be accommodated in the accommodation groove SGR of the tray TR to be transferred. When the display panel DP and the coating layer LMa are transferred, the tray TR may be shaken or inclined. Then, because the protrusions PR of the coating layer LMa are disposed on an outside of the peripheries of the display panel DP, the protrusions PR may contact an inner side of the tray TR earlier than the display panel DP. Accordingly, the display panel DP may not contact an outer side of the tray TR and damage to the display panel DP due to an impact may be prevented.

In an embodiment, before another process is performed after the display panel DP and the coating layer LMa are transferred, the flat part PLA and the protrusions PR may be separated. The protrusions PR may be separated from the flat part PLA along the removal groove STC. The protrusions PR may be separated from the lower surface of the display panel DP. As the removal grooves STC are defined, the protrusions PR and the flat part PLA may be easily separated.

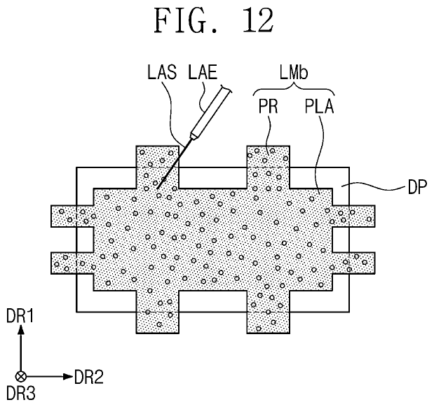

FIG. 12 is a view illustrating a coating layer, according to an embodiment.

In an embodiment, FIG. 12 is a plan view of a coating layer LMb, viewed from a rear side.

In an embodiment, because the display panel DP, the protrusions PR, and the flat part PLA of FIG. 12 are the same as the display panel DP, the protrusions PR, and the flat part PLA of FIG. 11B, a description thereof will be omitted and briefly made.

In an embodiment and referring to FIG. 12, a difference from FIG. 11B will be mainly described.

In an embodiment, the removal grooves STC (see FIG. 11C) may not be defined between the flat part PLA of the coating layer LMb and the protrusions PR. After the display panel DP and the coating layer LMb are transferred, a laser beam irradiating part LAE may irradiate a laser beam LAS to the coating layer LMb. The laser beam LAS may be irradiated to borders of the flat part PLA and the protrusions PR. The flat part PLA and the protrusions PR may be separated from each other by the laser beam LAS.

According to an embodiment, the impact preventing layer PTL having an area that is larger than that of the display panel DP may be disposed under the display panel DP. When the display panel DP and the impact preventing layer PTL are accommodated in the jig or the tray to be transferred, the impact preventing layer PTL may contact an interior of the jig or the tray earlier than the display panel DP. Accordingly, the display panel DP may be prevented from contacting the interior of the jig or the tray and a crack may be prevented from occurring in the display panel DP.

According to an embodiment, the coating layer may be disposed under the display panel DP. The coating layer may include the flat part PLA and the plurality of protrusions PR. When viewed on the plane, the protrusions PR may be disposed on an outside of the peripheries of the display panel DP. Accordingly, when the display panel DP and the coating layer are accommodated in the jig or the tray to be transferred, the protrusions PR may contact the interior of the jig or the tray earlier than the display panel DP. Accordingly, a crack may be prevented from occurring in the display panel DP by preventing the display panel DP from contacting the interior of the jig or the tray.

Although the description of the invention has been made above with reference to the embodiments, it may be understood that those skilled in the art or those having ordinary knowledge in the art may variously modify and changes the invention without departing from the spirit and technical scope of the invention. Furthermore, it should be understood that the embodiments disclosed in the present disclosure are not intended to limit the scope and/or the technical spirit of the invention. Moreover, the embodiments or parts of the embodiments may be combined in whole or in part without departing from the scope of the invention.

What is claimed is:

1. A display panel transfer method, the method comprising:
providing a coating layer onto a rear surface of a display panel; and
providing an impact preventing layer onto a rear surface of the coating layer,
wherein an area of the display panel is smaller than an area of the impact preventing layer, and wherein the area of the display panel is larger than an area of the coating layer when viewed on a plane.

2. The display panel transfer method of claim 1, wherein the impact preventing layer is defined by a cured protective resin and wherein the providing an impact preventing layer includes:
preparing a mold;
providing a protective resin into the mold;
providing the display panel and the coating layer onto the protective resin;
curing the protective resin to create the cured protective resin; and
removing the mold from the impact preventing layer.

3. The display panel transfer method of claim 2, wherein the mold is optically transparent.

4. The display panel transfer method of claim 2, wherein the protective resin includes an ultraviolet ray curing material.

5. The display panel transfer method of claim 4, wherein the protective resin includes an acryl-based or urethane-based material.

6. The display panel transfer method of claim 2, wherein the curing of the protective resin includes:
a primary curing operation of curing the protective resin by irradiating the protective resin with a first ultraviolet ray;
turning the mold and the protective resin over; and
curing the protective resin by irradiating a rear surface of the mold with a second ultraviolet ray,
wherein an intensity of the second ultraviolet ray is higher than an intensity of the first ultraviolet ray.

7. The display panel transfer method of claim 1, wherein the providing the display panel and the coating layer includes:
disposing a metal frame defining an opening, on the rear surface of the display panel; and
providing a resin onto the rear surface of the display panel through the opening,
wherein the opening and the display panel overlap each other, and wherein an area of the opening is smaller than the area of the display panel when viewed on a plane.

8. The display panel transfer method of claim 1, wherein peripheries of the impact preventing layer are disposed on an outer side of peripheries of the display panel when viewed on a plane.

9. The display panel transfer method of claim 8, further comprising:
providing the display panel, the coating layer, and the impact preventing layer into an accommodation groove defined in a tray or a jig.

10. The display panel transfer method of claim 9, wherein the peripheries of the impact preventing layer contact the tray or the jig, and the peripheries of the display panel are spaced apart from an inside of the tray or the jig.

11. The display panel transfer method of claim 9, further comprising:
removing the impact preventing layer from the coating layer.

12. The display panel transfer method of claim 1, wherein the coating layer includes:
a first base layer; and
a plurality of first fillers dispersed within the first base layer.

13. A display panel transfer method comprising:
preparing a display panel; and
providing a coating layer onto a rear surface of the display panel,
wherein the providing a coating layer includes:
providing a flat part, wherein the flat part extends along a first direction and a second direction crossing the first direction; and
providing a plurality of protrusions disposed adjacent to peripheries of the flat part,
wherein an area of the flat part is smaller than an area of the display panel when viewed on a plane.

14. The display panel transfer method of claim 13, wherein the flat part and the protrusions are formed at the same time.

15. The display panel transfer method of claim 14, wherein the protrusions are disposed on opposite sides of the flat part to be opposed to each other in the first direction and opposite sides of the flat part to be opposed to each other in the second direction.

16. The display panel transfer method of claim 13, wherein a plurality of removal grooves are defined between the flat part and the protrusions.

17. The display panel transfer method of claim 16, further comprising:
separating the flat part and the protrusions along the removal grooves.

18. The display panel transfer method of claim 15, further comprising:
separating the flat part and the protrusions by irradiating borders of the flat part and the protrusions with a laser beam.

19. The display panel transfer method of claim 13, wherein portions of the protrusions are disposed on an outer side of peripheries of the display panel when viewed on a plane.

20. The display panel transfer method of claim 19, wherein peripheries of the flat part are disposed on an inner side of the peripheries of the display panel when viewed on a plane.
